(19) United States
(12) Patent Application Publication
(10) Pub. No.: US 2020/0329598 A1
(43) Pub. Date: Oct. 15, 2020

(54) REFLOW OVEN CENTRAL MONITORING SYSTEM AND METHOD

(71) Applicant: HONGFUJIN PRECISION ELECTRONICS (TIANJIN) CO.,LTD., Tianjin (CN)

(72) Inventors: SHIH-LIN WU, New Taipei (TW); BAO-WANG GENG, Tianjin (CN)

(21) Appl. No.: 16/412,849

(22) Filed: May 15, 2019

(30) Foreign Application Priority Data
Apr. 11, 2019 (CN) 201910288747.4

(51) Int. Cl. H05K 13/08; H05K 13/04; B23K 1/008

(52) U.S. Cl. CPC H05K 13/0817; B23K 2101/36; B23K 1/008; H05K 13/0465

(57) ABSTRACT

A reflow oven central monitoring method includes setting standard operating parameters of a reflow oven, acquiring real-time operating parameters of the reflow oven, and comparing the real-time operating parameters respectively to the standard operating parameters to determine whether a difference exceeds a predetermined range. If the difference exceeds the predetermined range, workpieces are stopped from flowing into the reflow oven, a position of abnormal workpieces is locked, an alarm signal is sent, a prompt of locking the position of the abnormal workpieces is sent, and at least one of the real-time operating parameters is provided for inspection of the abnormal workpieces. The standard operating parameters include a standard temperature of each reheating zone of the reflow oven, a conveying speed of the reflow oven, and an oxygen content. The real-time operating parameters respectively correspond to the standard operating parameters.

### FIELD

The subject matter herein generally relates to a reflow oven central monitoring system and method.

### BACKGROUND

Reflow ovens are widely used in Surface Mount Technology (SMT) for reflow soldering. However, when operation of the reflow oven is abnormal, an operator cannot immediately know the situation to stop the reflow oven.

### BRIEF DESCRIPTION OF THE DRAWINGS

Implementations of the present disclosure will now be described, by way of embodiments, with reference to the attached figures.

FIG. 1 is a block diagram of an embodiment of a reflow oven central monitoring system.

FIGS. 2-6 are flowcharts of a reflow oven central monitoring method.

### DETAILED DESCRIPTION

It will be appreciated that for simplicity and clarity of illustration, where appropriate, reference numerals have been repeated among the different figures to indicate corresponding or analogous elements. Additionally, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “comprising” means “including, but not necessarily limited to”; it specifically indicates open-ended inclusion or membership in a so-described combination, group, series and the like.

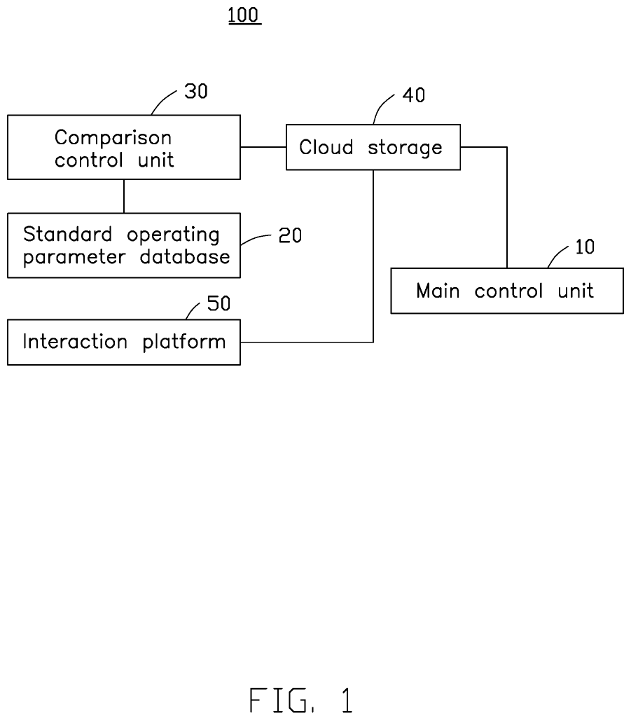

FIG. 1 shows an embodiment of a reflow oven central monitoring system 100 including a main control unit 10, a standard operating parameter database 20, and a comparison control unit 30.

The main control unit 10 is configured to control a reflow oven (not shown) and collect real-time operating parameters of the reflow oven.

The standard operating parameter database 20 is configured to store standard operating parameters of the reflow oven. The standard operating parameters include a type of the reflow oven, a corresponding line (such as a production line), a standard temperature of each temperature zone of the reflow oven, a conveying speed of the reflow oven, and an oxygen content of each temperature zone. The standard operating parameters refer to operating parameters when the reflow oven is in a normal operating state.

In other embodiments, the standard operating parameters may be set as one or more of the standard operating parameters described above as required.

The real-time operating parameters of the reflow oven collected by the main control unit 10 correspond to the standard operating parameters.

The comparison control unit 30 is communicatively coupled to the main control unit 10 and the standard operating parameter database 20 to obtain the real-time operating parameters from the main control unit 10 and obtain the standard operating parameters from the standard operating parameter database 20.

The comparison control unit 30 compares the real-time operating parameters to the standard operating parameters to obtain a difference between the real-time operating parameters and the respective standard operating parameters and determine whether the difference exceeds a predetermined range. When the difference exceeds the predetermined range, workpieces that are inside the reflow oven are abnormal workpieces.

When the difference exceeds the predetermined range, the comparison control unit 30 stops workpieces from flowing into the reflow oven, locks a position of the abnormal workpieces, sends an alarm signal, sends a prompt of locking the position of the abnormal workpieces, and provides at least one of the real-time operating parameters for inspection of the abnormal workpieces.

Specifically, the comparison control unit 30 sends a signal to the main control unit 10 when the difference exceeds the predetermined range, and the main control unit 10 sends the signal to the corresponding line to stop the line, thereby stopping the workpieces from flowing into the reflow oven and locking the abnormal workpieces in an abnormal temperature zone of the reflow oven. A display prompts that the abnormal workpieces have been locked, and the real-time operating parameters of the abnormal workpieces can be checked according to a PPID, and the comparison control unit 30 controls an alarm device to send an alarm signal. In a specific implementation, the above operations may be selected as needed, rearranged, or combined.

For example, when the real-time temperature of the temperature zone exceeds a standard temperature of the temperature zone by 5° C., the comparison control unit 30 sends a signal to the main control unit 10, and the main control unit 10 controls the reflow oven to stop and locks the abnormal workpiece in the abnormal temperature zone. The comparison control unit 30 controls an alarm device to output an alarm signal or send a prompt email.

When a real-time transmission speed of the temperature zone exceeds a standard transmission speed of the temperature zone by 3 cm/s, the comparison control unit 30 sends a signal to the main control unit 10, and the main control unit 10 controls the reflow oven to stop and locks the abnormal workpiece in the abnormal temperature zone. The comparison control unit 30 controls an alarm device to output an alarm signal or send a prompt email.

When a real-time oxygen content of the temperature zone exceeds a standard oxygen content of the temperature zone by 1000 PPM, the comparison control unit 30 sends a signal to the main control unit 10, and the main control unit 10 controls the reflow oven to stop and locks the abnormal workpiece in the abnormal temperature zone. The comparison control unit 30 controls an alarm device to output an alarm signal or send a prompt email.

Standard operating parameter data stored in the standard operating parameter database 20 can be established according to a predetermined format. For example, the standard operating parameter data includes a type of the reflow oven and corresponding standard operating parameters of the type of reflow oven, so that the comparison control unit 30 can obtain the standard operating parameters corresponding to the type of the reflow oven from the standard operating parameter database 20.

In one embodiment, the reflow oven central monitoring system 100 further includes a cloud storage 40.

The cloud storage 40 is communicatively coupled to the main control unit 10 and the comparison control unit 30 to implement data transmission and interaction.

The main control unit 10 reads real-time operating parameters corresponding to each temperature zone of the reflow oven, and uploads the real-time operating parameters to the cloud storage 40. The comparison control unit 30 accesses the cloud storage 40 to acquire the real-time operating parameters. Thus, a storage record of the real-time operating parameters is established, and the storage record can be conveniently queried.

In one embodiment, the reflow oven central monitoring system 100 further includes an interaction platform 50.

The interaction platform 50 is configured to display the standard operating parameters and the real-time operating parameters in real time. The interaction platform 50 is further configured to perform at least one of remotely accessing the standard operating parameters and the real-time operating parameters, querying the cloud storage 40, displaying abnormal information, and displaying alarm information.

In one embodiment, the interaction platform 50 is remotely accessed through a network by a mobile terminal, such as a computer, a tablet computer, or a mobile phone, to query an operation status and historical operational data of the reflow oven.

The interaction platform 50 can convert the real-time operating parameters, the standard operating parameters, the abnormal information, the alarm information, and the like into a network kanban according to a predetermined model, so as to facilitate real-time and intuitive monitoring.

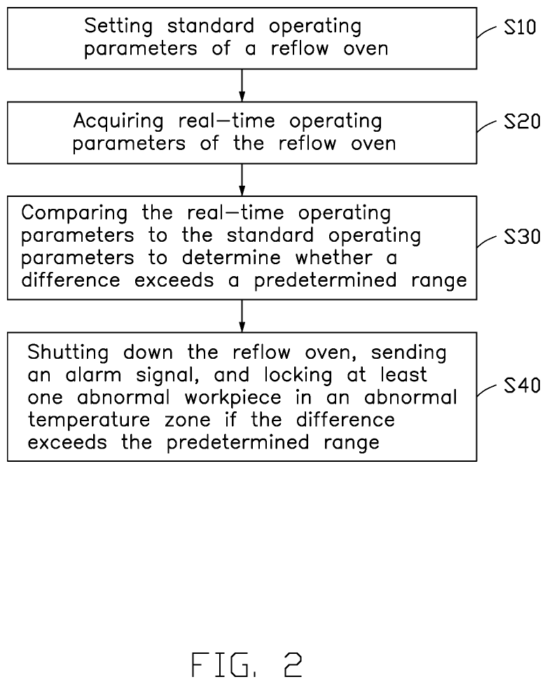

FIGS. 2-6 illustrate a flowchart of a reflow oven central monitoring method. The method is provided by way of embodiment, as there are a variety of ways to carry out the method. The method described below can be carried out using the configurations illustrated in FIG. 1, for example, and various elements of these figures are referenced in explaining the example method. Each block shown in FIGS. 2-6 represents one or more processes, methods, or subroutines carried out in the example method. Furthermore, the illustrated order of blocks is by example only, and the order of the blocks can be changed. Additional blocks can be added or fewer blocks can be utilized, without departing from this disclosure.

At block S10, standard operating parameters of a reflow oven are set. The standard operating parameters include a standard temperature of each reheating zone of the reflow oven, a conveying speed of the reflow oven, and an oxygen content.

At block S20, real-time operating parameters of the reflow oven are acquired. The real-time operating parameters respectively correspond to the standard operating parameters.

At block S30. the real-time operating parameters are respectively compared to the standard operating parameters to determine whether a difference exceeds a predetermined range.

At block S40, if the difference exceeds the predetermined range, the reflow oven is shut down, an alarm signal is sent, and at least one abnormal workpiece is locked in an abnormal temperature zone.

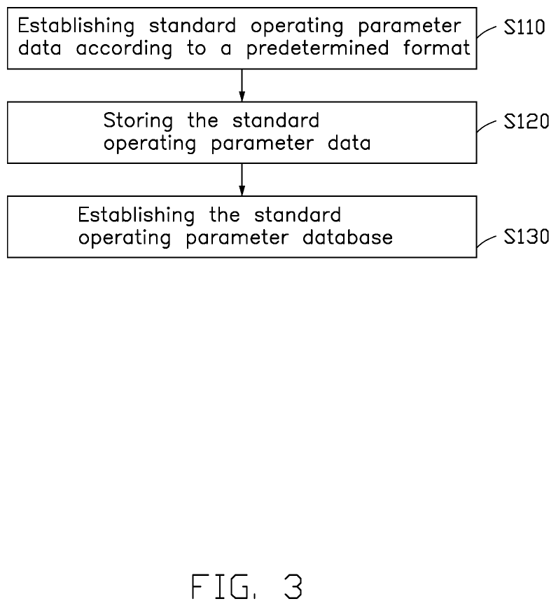

FIG. 3 shows one embodiment of a method of setting the standard operating parameters of the reflow oven.

At block S110, standard operating parameter data is established according to a predetermined format. The standard operating parameter data includes a type of the reflow oven and corresponding standard operating parameters of the type of reflow oven.

At block S120, the standard operating parameter data is stored.

At block S130, the standard operating parameter database is established.

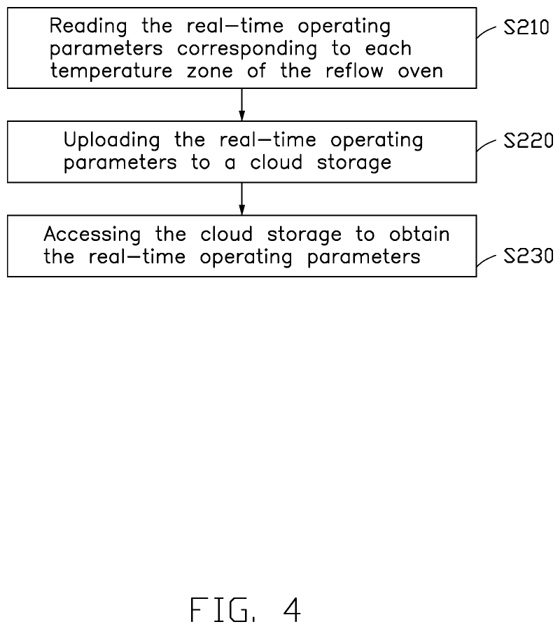

FIG. 4 shows one embodiment of a method of obtaining the real-time operating parameters of the reflow oven.

At block S210, the real-time operating parameters corresponding to each temperature zone of the reflow oven are read.

At block S220, the real-time operating parameters are uploaded to a cloud storage.

At block S230, the cloud storage is accessed to obtain the real-time operating parameters.

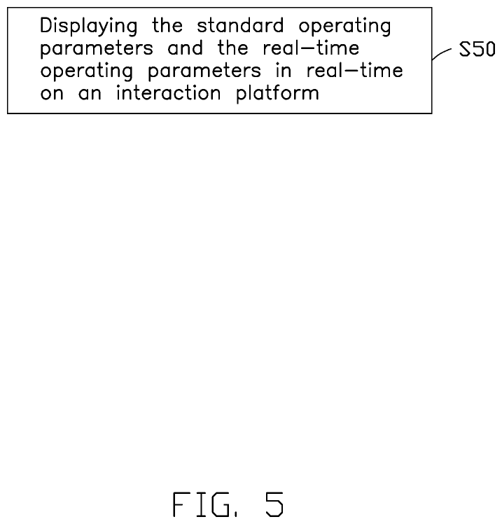

Referring to FIG. 5, at block S50, the standard operating parameters and the real-time operating parameters are displayed in real-time on an interaction platform.

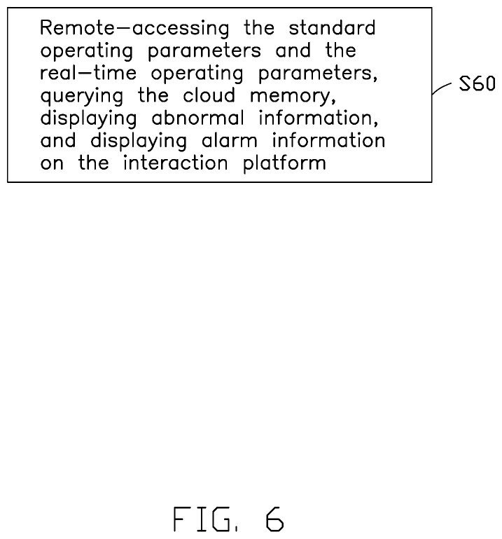

Referring to FIG. 6, at block S60, the standard operating parameters and the real-time operating parameters are remote-accessed, the cloud memory is queried, abnormal information is displayed, and alarm information is displayed on the interaction platform.

The standard operating parameters of the reflow oven are set, and the real-time operating parameters of the reflow oven are obtained and compared to the standard operating parameters to determine whether the real-time operating parameters exceed the standard operating parameters by a predetermined range to determine whether the temperature zones of the reflow oven are abnormal. If the temperature zones are abnormal, the reflow oven is shut down, an alarm signal is sent, and at least one of the abnormal workpieces in the abnormal temperature zone is locked in position, thereby realizing central monitoring of the reflow oven and improving reflow soldering.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure up to, and including, the full extent established by the broad general meaning of the terms used in the claims.

What is claimed is:

1. A reflow oven central monitoring method comprising:
setting standard operating parameters of a reflow oven, the standard operating parameters comprising a standard temperature of each reheating zone of the reflow oven, a conveying speed of the reflow oven, and an oxygen content;
acquiring real-time operating parameters of the reflow oven, the real-time operating parameters respectively corresponding to the standard operating parameters;
comparing the real-time operating parameters respectively to the standard operating parameters to determine whether a difference exceeds a predetermined range;
stopping workpieces from flowing into the reflow oven, locking a position of the abnormal workpieces, sending an alarm signal, sending a prompt of locking the position of the abnormal workpieces, and providing at least one of the real-time operating parameters for inspection of the abnormal workpieces when the difference exceeds the predetermined range.

2. The reflow oven central monitoring method of claim 1, wherein the standard operating parameters of the reflow oven are set by:
establishing standard operating parameter data according to a predetermined format, the standard operating parameter data comprising a type of the reflow oven and corresponding standard operating parameters of the type of reflow oven;
storing the standard operating parameter data; and
establishing the standard operating parameter database.

3. The reflow oven central monitoring method of claim 2, wherein the real-time operating parameters of the reflow oven are acquired by:
reading the real-time operating parameters corresponding to each temperature zone of the reflow oven;
uploading the real-time operating parameters to a cloud storage;
accessing the cloud storage to obtain the real-time operating parameters.

4. The reflow oven central monitoring method of claim 3 further comprising:
displaying the standard operating parameters and the real-time operating parameters in real-time on an interaction platform.

5. The reflow oven central monitoring method of claim 4 further comprising:
remote-accessing the standard operating parameters and the real-time operating parameters on the interaction platform;
querying the cloud memory on the interaction platform;
displaying abnormal information on the interaction platform; and
displaying alarm information on the interaction platform.

6. A reflow oven central monitoring system comprising:
a main control unit configured to control a reflow oven and collect real-time operating parameters of the reflow oven;
a standard operating parameter database configured to store standard operating parameters of the reflow oven, the standard operating parameters comprising a type of the reflow oven, a corresponding line, a standard temperature of each temperature zone of the reflow oven, a conveying speed of the reflow oven, and an oxygen content of each temperature zone;
a comparison control unit communicatively coupled to the main control unit and the standard operating parameter database to obtain the real-time operating parameters from the main control unit and obtain the standard operating parameters from the standard operating parameter database; wherein:
the comparison control unit is configured to compare the real-time operating parameters to the standard operating parameters to obtain a difference between the real-time operating parameters and the respective standard operating parameters and determine whether a difference exceeds a predetermined range;
when the difference exceeds the predetermined range, the comparison control unit stops workpieces from flowing into the reflow oven, locks a position of the abnormal workpieces, sends an alarm signal, sends a prompt of locking the position of the abnormal workpieces, and provides at least one of the real-time operating parameters for inspection of the abnormal workpieces.

7. The reflow oven central monitoring system of claim 6, wherein:
the standard operating parameter data stored in the standard operating parameter database is established according to a predetermined format;
the standard operating parameter data includes a type of the reflow oven and corresponding standard operating parameters of the type of reflow oven;
the comparison control unit obtains the standard operating parameters corresponding to the type of the reflow oven from the standard operating parameter database.

8. The reflow oven central monitoring system of claim 7 further comprising a cloud storage communicatively coupled to the main control unit 10 and the comparison control unit, wherein:
the main control unit reads real-time operating parameters corresponding to each temperature zone of the reflow oven, and uploads the real-time operating parameters to the cloud storage;
the comparison control unit accesses the cloud storage to acquire the real-time operating parameters.

9. The reflow oven central monitoring system of claim 8 further comprising an interaction platform configured to display the standard operating parameters and the real-time operating parameters in real time.

10. The reflow oven central monitoring system of claim 9, wherein:
the interaction platform is further configured to remotely access the standard operating parameters and the real-time operating parameters, query the cloud storage, display abnormal information, and display alarm information.

11. The reflow oven central monitoring system of claim 10, wherein:
the interaction platform converts the real-time operating parameters, the standard operating parameters, the abnormal information, and the alarm information into a network kanban according to a predetermined model.
